(19) United States
(12) Patent Application Publication
(10) Pub. No.: US 2010/0047582 A1
(43) Pub. Date: Feb. 25, 2010

(54) LAMINATED BODY FOR RESIN GLASS AND METHOD FOR MANUFACTURING THE SAME

(76) Inventors: Toshihisa Shimo, Aichi-ken (JP); Hisashi Muramatsu, Aichi-ken (JP); Hiroyasu Hiramatsu, Aichi-ken (JP); Toshiro Kondo, Aichi-ken (JP); Makoto Kato, Aichi-ken (JP); Kenzo Fukumori, Aichi-ken (JP); Yosihide Katagiri, Aichi-ken (JP); Takayuki Nagai, Aichi-ken (JP); Toshio Watanabe, Aichi-ken (JP)

Correspondence Address: MORGAN & FINNEGAN Transition Team;C/O Locke Lord Bissell & Liddell, 3 WORLD FINANCIAL CENTER, NEW YORK, NY, 10281-2101, US

(21) Appl. No.: 12/302,441

(22) PCT Filed: May 17, 2007
(86) PCT No.: PCT/JP2007/060098

§ 371 Date: Aug. 7, 2009

(30) Foreign Application Priority Data
May 26, 2006 (JP) 2006-147343

(51) Int. Cl. B32B 9/04; B32B 27/36; B32B 27/06; B32B 38/00; B32B 15/08; C23C 14/28

(52) U.S. Cl. 428/412; 428/447; 428/419; 156/272.8

(57) ABSTRACT

A laminated body for resin glass comprising a polymer substrate for resin glass, an inorganic layer formed by causing fine particles of at least one substance selected from the group consisting of aluminum, silicon, titanium, an aluminum compound, a silicon compound and a titanium compound to adhere onto the polymer substrate for resin glass, and an alkoxysilane-containing hard coating layer laminated to the polymer substrate for resin glass having the inorganic layer interposed therebetween.

### TECHNICAL FIELD

The present invention relates to a laminated body for resin glass and a method for manufacturing the same.

### BACKGROUND OF THE INVENTION

Generally, a polymer substrate for resin glass such as a polycarbonate resin has low adhesion to a hard coating due to low surface free energy thereof. As a result, sufficient adhesion generally can not be obtained without some sort of surface treatment (pre-coating treatment) being performed. Consequently, various primer coating has been applied conventionally as a method of this pre-coating treatment (“Polycarbonate Resin Handbookl”, edited by Seiichi Honma, Nikkan Kogyo Shimbun Ltd., published at Aug. 28, 1992).

However, there is a problem that this kind of primer coating has a large environmental load because the primer is often diluted with an organic solvent. In addition, this kind of primer coating requires substantial time because the primer needs to be applied multiple times. Moreover, this kind of primer coating also has a problem in economical efficiency because the primer needs to contain a large amount of an ultraviolet absorber in order to prevent ultraviolet degradation of a polymer substrate for resin glass.

### DISCLOSURE OF THE INVENTION

The present invention has been made in consideration of the above-described problems in the conventional techniques. An object of the present invention is to provide a laminated body for resin glass, and a method for manufacturing the laminated body for resin glass capable of efficiently and reliably manufacturing the laminated body for resin glass. The laminated body for resin glass has sufficiently high adhesion between a polymer substrate for resin glass and a hard coating layer without a conventional primer coating being performed, and can exhibit excellent abrasion-resistance as well as high weatherability by which the polymer substrate for resin glass is sufficiently prevented from degradation caused by ultraviolet irradiation.

The present inventers have earnestly studied in order to archive the above object. As a result, the inventors have revealed that a laminated body for resin glass which has sufficiently high adhesion between a polymer substrate for resin glass and a hard coating layer without a conventional primer coating being performed, and which can exhibit excellent abrasion-resistance as well as high weatherability by which the polymer substrate for resin glass is sufficiently prevented from degradation caused by ultraviolet irradiation, can surprisingly be obtained by causing fine particles of, for example, a specific metal to adhere onto the polymer substrate for resin glass and laminating a hard coating layer containing a specific organic compound to the polymer substrate having interposed therebetween an inorganic layer formed by the adhesion of the particles. This discovery has led the inventors to complete the present invention.

To be more specific, the laminated body for resin glass of the present invention comprises a polymer substrate for resin glass, an inorganic layer formed by causing fine particles of at least one substance selected from the group consisting of aluminum, silicon, titanium, an aluminum compound, a silicon compound and a titanium compound to adhere onto the polymer substrate for resin glass and an alkoxysilane-containing hard coating layer laminated to the polymer substrate for resin glass having the inorganic layer interposed therebetween.

The above-mentioned inorganic layer according to the present invention is preferably a layer formed: by irradiating laser light to a surface of a base material to generate vacuum-ultraviolet light having a wavelength of 50 nm to 100 nm and flying particles; and by causing the flying particles to adhere onto the polymer substrate for resin glass with irradiation of the vacuum-ultraviolet light, said base material being made of a material comprising at least one substance selected from the group consisting of aluminum, silicon, titanium, an aluminum compound, a silicon compound and a titanium compound.

In addition, a method for manufacturing a laminated body for resin glass of the present invention comprises the steps of, forming an inorganic layer by causing fine particles of at least one substance selected from the group consisting of aluminum, silicon, titanium, an aluminum compound, a silicon compound and a titanium compound to adhere onto a polymer substrate for resin glass, and laminating an alkoxysilane-containing hard coating layer to the polymer substrate for resin glass having the inorganic layer interposed therebetween.

In the above-mentioned method for manufacturing the laminated body for resin glass of the present invention, the step of forming the inorganic layer is preferably a step of forming an inorganic layer: by irradiating laser light to a surface of a base material to generate vacuum-ultraviolet light having a wavelength of 50 nm to 100 nm and flying particles; and by causing the flying particles to adhere onto the polymer substrate for resin glass with irradiation of the vacuum-ultraviolet light, said base material being made of a material comprising at least one substance selected from the group consisting of aluminum, silicon, titanium, an aluminum compound, a silicon compound and a titanium compound.

Moreover, in the above-mentioned method for manufacturing the laminated body for resin glass of the present invention, the laser light is preferably a pulsed laser light having a pulse width of 100 picoseconds to 100 nanoseconds and an irradiation intensity of 10⁶ W/cm² to 10¹² W/cm².

Furthermore, in the above-mentioned method for manufacturing the laminated body for resin glass of the present invention, it is preferable that the flying particles are caused to adhere onto the surface of the polymer substrate for resin glass under a reduced pressure condition and/or a shielding gas atmosphere comprising at least one gas selected from the group consisting of hydrogen gas, helium gas, neon gas and argon gas.

The above-mentioned polymer substrate for resin glass according to the present invention preferably comprises at least one resin selected from the group consisting of a polycarbonate resin, a polymethyl methacrylate resin, a methyl methacrylate resin, a transparent acrylonitrile butadiene styrene resin, a transparent polystyrene resin, a transparent epoxy resin, a polyarylate, a polysulfone, a polyethersulfone, a transparent nylon resin, a transparent polybutylene terephthalate, a transparent fluororesin, poly-4-methylpentene-1, a transparent phenoxy resin, a polyimide resin and a transparent phenol resin, and more preferably comprises a substrate consisting of a polycarbonate resin.

Here, it is not known exactly why the laminated body for resin glass and the method for manufacturing the same of the present invention can achieve the above object. However, the inventors of the present invention speculate as follows. First, in the present invention, the surface of polymer substrate for resin glass is maintained in an active state because fine particles of at least one substance selected from the group consisting of aluminum, silicon, titanium, an aluminum compound, a silicon compound and a titanium compound, which has high surface energy, adhere onto the surface of the polymer substrate for resin glass, which has low surface free energy. Therefore, adhesion between a hard coating layer and the polymer substrate for resin glass is increased. Moreover, in the present invention, the hard coating layer contains an alkoxysilane. Such an alkoxysilane has high reactivity to fine particles of at least one substance selected from the group consisting of aluminum, silicon, titanium, an aluminum compound, a silicon compound and a titanium compound and readily react with the particles. For this reason, the hard coating layer of the present invention can exhibit higher adhesion than hard coating layers which uses other materials. Furthermore, surprisingly, it has been found that a certain specific inorganic layer according to the present invention exhibits high weatherability. The inventors of the present invention speculate that this is because the inorganic layer has high reflectance to the ultra-violet light having a wavelength region which deteriorates the polymer substrate for resin glass.

The present invention makes it possible to provide a laminated body for resin glass, and a method for manufacturing the laminated body for resin glass capable of efficiently and reliably manufacturing the laminated body for resin glass. The laminated body for resin glass has sufficiently high adhesion between a polymer substrate for resin glass and a hard coating layer without a conventional primer coating being performed, and can exhibit excellent abrasion-resistance as well as high weatherability by which the polymer substrate for resin glass is sufficiently prevented from degradation caused by ultraviolet irradiation.

### BRIEF DESCRIPTION OF THE DRAWINGS

FIG. 1 is a schematic diagram of a basic configuration of a preferred embodiment of preferable equipment to form an inorganic layer.

FIG. 2 is a schematic diagram showing positional relationship of a target and a polymer substrate for resin glass arranged in a treatment container.

### DETAILED DESCRIPTION OF THE PREFERRED EMBODIMENTS

The present invention will be described below in detail according to preferred embodiments.

A laminated body for resin glass of the present invention will be described. To be more specific, the laminated body for resin glass of the present invention includes: a polymer substrate for resin glass; an inorganic layer formed by causing fine particles of at least one substance selected from the group consisting of aluminum, silicon, titanium, an aluminum compound, a silicon compound and a titanium compound to adhere onto the polymer substrate for resin glass; and an alkoxysilane-containing hard coating layer laminated to the polymer substrate for resin glass having the inorganic layer interposed therebetween.

The polymer substrate for resin glass according to the present invention may be a substrate formed with a polymer resin that can be used for resin glass and not particularly limited. As the polymer substrate, preferable is a substrate including at least one resin selected from the group consisting of a polycarbonate resin, a polymethyl methacrylate resin, a methyl methacrylate resin, a transparent acrylonitrile butadiene styrene resin, a transparent polystyrene resin, a transparent epoxy resin, a polyarylate, a polysulfone, a polyethersulfone, a transparent nylon resin, a transparent polybutylene terephthalate, a transparent fluororesin, poly-4-methylpentene-1, a transparent phenoxy resin, a polyimide resin and a transparent phenol resin. Of these polymer substrates for resin glass, a polymer substrate for resin glass formed of a polycarbonate resin is specifically preferable from the viewpoint of having higher transparency and exhibiting excellent toughness.

The thickness of the polymer substrate for resin glass is not particularly limited because the thickness varies as appropriate depending on a design of an obtained laminated body for resin glass. The thickness of the polymer substrate is preferably 1 to 10 mm, for example, in automotive and other use. If the polymer substrate is thinner than the lower limit, the laminated body for resin glass tends to less practical because the laminated body for resin glass has such a low rigidity as to warp. On the other hand, if the thickness is thicker than the upper limit, the laminated body for resin glass tends to less practical because the laminated body for resin glass becomes heavy. In addition, a shape of such a polymer substrate for resin glass is not particularly limited, and various shapes can be selected as appropriate depending on an application of an obtained laminated body for resin glass.

An inorganic layer according to the present invention is formed by causing fine particles of at least one substance selected from the group consisting of aluminum, silicon, titanium, an aluminum compound, a silicon compound and a titanium compound to adhere onto the polymer substrate for resin glass.

Such an aluminum compound, a silicon compound and a titanium compound are not particularly limited, and include: oxide, nitride, carbide and sulfide of any of aluminum, silicon and titanium; and complex compound of aluminum, silicon and titanium. Such an aluminum compound, a silicon compound and a titanium compound specifically includes silica, alumina, glass, silica glass, kaolin, mica, talc, clay, hydrated alumina, wollastonite, potassium titanate, titanium oxide, silicon carbide and silicon nitride. Moreover, among these aluminum compounds, silicon compounds and titanium compounds, from the viewpoint of higher reactivity to an alkoxysilane contained in a hard coating layer to provide higher adhesion to the hard coating layer, silica, alumina, glass, silica glass, kaolin, mica, talc, clay, hydrated alumina, wollastonite, potassium titanate, titanium oxide are preferable, and silica, alumina, glass, silica glass, kaolin, titanium oxide are more preferable.

For such an inorganic layer, preferable is a layer formed by irradiating laser light to a surface of a base material made of a material containing at least one substance selected from the group consisting of aluminum, silicon, titanium, an aluminum compound, a silicon compound and a titanium compound to generate vacuum-ultraviolet light having a wavelength of 50 nm to 100 nm and flying particles and by causing the flying particles to adhere onto the polymer substrate for resin glass with irradiation of the vacuum-ultraviolet light. Such an inorganic layer tends to increase adhesion between the polymer substrate for resin glass and the hard coating layer.

The term vacuum-ultraviolet light having a wavelength of 50 nm to 100 nm here means vacuum-ultraviolet light having at least a part of wavelength region from 50 nm to 100 nm, and it is preferable that the vacuum-ultraviolet light satisfies at least one condition selected from the following conditions.

(i) The vacuum-ultraviolet light has at least one peak of light intensity in the wavelength region from 50 nm to 100 nm;
(ii) A total energy of light in the region from 50 nm to 100 nm is higher than a total energy of light in the region from 100 nm to 150 nm;
(iii) A total energy of light in the region from 50 nm to 100 nm is higher than a total energy of light in the region of 50 nm or less;
(iv) An energy density of light in the region from 50 nm to 100 nm is 0.1 μJ/cm² to 10 mJ/cm² (more preferably 1 μJ/cm² to 100 μJ/cm²) on the polymer substrate for resin glass. Note that, if the energy density on the substrate is lower than 0.1 μJ/cm², required time for treatment tends to be excessively long. In contrast, if the energy density is higher than 10 mJ/cm², the substrate tends to be decomposed.

Moreover, consider a case where this method of causing the flying particles to adhere by laser light irradiation is employed. When the flying particles are caused to adhere onto a surface of the polymer substrate for resin glass under a shielding gas atmosphere, for example, use of a container whose inner pressure is reduced results in vacuum-ultraviolet light irradiation to the surface of the polymer substrate for resin glass without absorption of the light by vacuum-ultraviolet light absorbing substances such as oxygen in air. As a result, the surface of the polymer substrate for resin glass tends to be activated more efficiently. In addition, when it is treated under a shielding gas atmosphere, vacuum-ultraviolet light can be irradiated to the surface of the polymer substrate for resin glass without absorption of the light by vacuum-ultraviolet light absorbing substrates even not in reduced pressure. As a result, the surface of the substrate tends to be activated more efficiently. Moreover, in the latter case, use of a vacuum pump or a pressure-resistant container is not required in contrast to the former case, so that the latter case tends to be more preferable in terms of simplicity of equipment and lower cost.

A thickness of the inorganic layer is preferably 0.5 to 1,000 nm, and more preferably 1 to 100 nm. If the thickness of the inorganic layer is thinner than the lower limit, a surface free energy tends not to become sufficiently high because an amount of particles forming the inorganic layer is small. On the other hand, if thickness of the inorganic layer is thicker than the upper limit, the inorganic layer tends to peel off spontaneously by a stress generated from residual strain. The inorganic layer is not necessarily in the form of film, and may be formed by causing the fine particles to adhere dispersedly.

Although an average particle diameter of the fine particles is not particularly limited, the diameter is preferably about 0.1 to 500 nm. If the average particle diameter is smaller than the lower limit, treatment under a shielding gas atmosphere tends to be difficult. On the other hand, when the average particle diameter is larger than the upper limit, treatment tends to become nonuniform.

A hard coating layer of the present invention is an alkoxysilane-containing hard coating layer laminated onto the polymer substrate for resin glass having the inorganic layer interposed therebetween. As described above, the hard coating layer of the present invention contains an alkoxysilane. Moreover, the alkoxysilane has high reactivity to at least one substance selected from the group consisting of aluminum, silicon, titanium, an aluminum compound, a silicon compound and a titanium compound which form the inorganic layer. Therefore, molecules of the alkoxysilane and the surface of the polymer substrate for resin glass are bonded strongly, so that high adhesion of the hard coating layer can be achieved.

A material forming the hard coating layer may contain an alkoxysilane, and is not particularly limited. Any commercially available hard coating material containing an alkoxysilane can be used. Such commercially available hard coating materials include, for example, Tossguard 510 (manufactured by GE Toshiba Silicone Co., Ltd.), Solguard NP-720 and Solguard NP-730 (manufactured by Nippon Dacro shamrock Co., Ltd.) and KP-851 and KP-854 (manufactured by Shin-Etsu Chemical Co., Ltd.).

For these hard coating materials, a compound containing an organopolysiloxane composition including a condensation compound of a hydrolyzed organosilane represented by the general formula (I) as an alkoxysilane:

(R¹)ₙSi(OR²)₄₋ₙ (1)

(where each R¹ may be the same or different and represents a monovalent organic group containing 1 to 10 carbon atoms; n represents an integer of 0 to 2; and each R² may be the same or different and represents a hydrogen atom or monovalent organic group) is preferable.

Although a thickness of such a hard coating layer is not particularly limited, a thickness after heat curing is preferably 0.2 to 20 μm, and more preferably 0.5 to 10 μm. If the thickness of such a hard coating layer is thinner than the lower limit, a desired hardness and abrasion resistance tend not to be obtained. On the other hand, if the thickness of this hard coating layer is thicker than the upper limit, cracks tend to be generated by stress generated during heat curing and adhesion tends to become lower.

The laminated body for resin glass of the present invention has been described above, and a method for manufacturing a laminated body for resin glass of the present invention which is preferable to produce the above-mentioned laminated body for resin glass of the present invention will be described below.

A method for manufacturing a laminated body for resin glass of the present invention includes the steps of forming an inorganic layer by causing fine particles of at least one substance selected from the group consisting of aluminum, silicon, titanium, an aluminum compound, a silicon compound and a titanium compound to adhere onto a polymer substrate for resin glass (an inorganic layer forming process), and laminating an alkoxysilane-containing hard coating layer to the polymer substrate for resin glass having the inorganic layer interposed therebetween (a hard coating layer laminating process).

### (Inorganic Layer Forming Process)

Such a process of forming the inorganic layer is not particularly limited and, for example, a process of forming the inorganic layer by employing a laser ablation method, a process of forming the inorganic layer by employing a plasma CVD method and a process of forming the inorganic layer by employing a sputtering method can be employed. Of these processes for forming the inorganic layer, employing the process of forming the inorganic layer by employing a laser ablation method is preferable from the viewpoint of enabling higher adhesion of a hard coating layer to be achieved. In addition, of processes for forming the inorganic layer by employing laser ablation methods, employing a process of forming the inorganic layer by irradiating laser light to a surface of a base material made of a material comprising at least one substance selected from the group consisting of aluminum, silicon, titanium, an aluminum compound, a silicon compound and a titanium compound to generate vacuum-ultraviolet light having a wavelength of 50 nm to 100 nm and flying particles and forming the inorganic layer by causing the flying particles to adhere onto the polymer substrate for resin glass with irradiation of the vacuum-ultraviolet light is preferable.

A preferred embodiment of the process of forming the inorganic layer by employing a laser ablation method as a preferable inorganic layer forming process will be described below in detail with referring drawings. In description and drawings below, the same symbol is given to the same or a corresponding element and overlapping descriptions will be omitted.

First, preferable equipment for performing a process of forming an inorganic layer by employing laser ablation methods will be described.

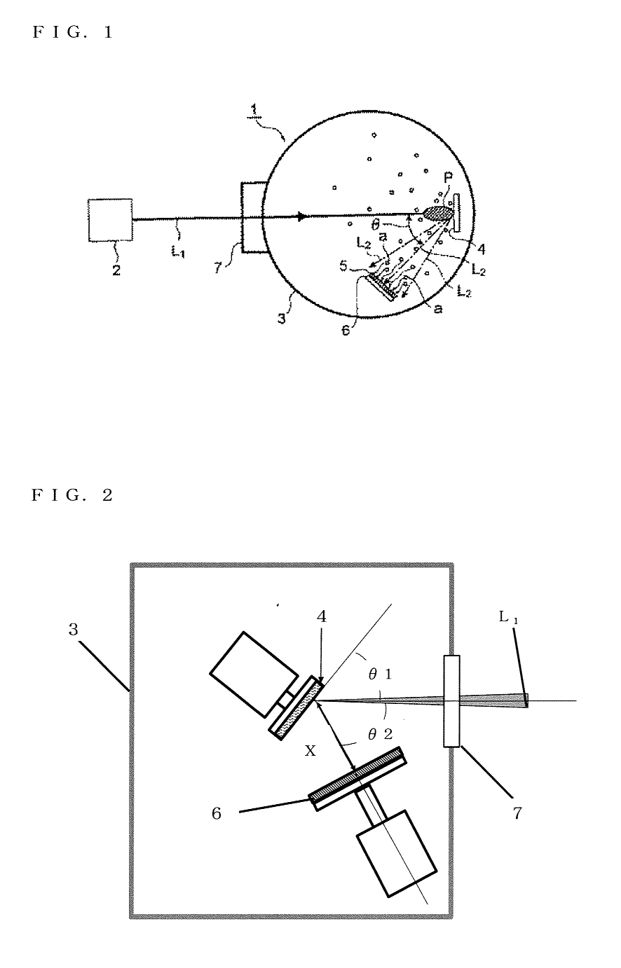

FIG. 1 is a schematic diagram of a basic configuration of a preferred embodiment of preferable equipment for performing a process of forming the inorganic layer. The equipment shown in FIG. 1 is composed as so-called laser ablation equipment 1. To be more specific, the laser ablation equipment 1 shown in FIG. 1 includes a laser source 2 and a treatment container 3 into which laser light L₁ generated from the laser source 2 is introduced, and inside the treatment container 3, a target 4 to which the laser light L₁ is irradiated and a substrate 6 on a surface of which an activated inorganic layer 5 will be formed are placed.

The laser source 2 may be a laser light generator which can irradiate pulsed laser light having a pulse width of 100 picoseconds to 100 nanoseconds, and not particularly limited. For example, the laser source 2 is composed of a YAG laser equipment or an excimer laser equipment, and being composed of a YAG laser equipment is particularly preferable. The laser source 2 is placed at the position of irradiating laser light L₁ to the target 4 which is located inside the treatment container 3. In addition, although not illustrated, lenses and mirrors can be placed as appropriate at a midpoint in a light path of the laser light L₁ to adjust energy density and an irradiation angle of the laser light for the purpose of effective generation of vacuum-ultraviolet light L₂ and flying particles a containing aluminum, silicon, titanium and a compound thereof from the surface of the target 4 when the laser light L₁ is irradiated to the target 4. Particularly, by placing a condenser lens (not illustrated) inside or outside the treatment container 3, an irradiation intensity of the pulsed laser light L₁ irradiated to the target 4 is preferably adjusted from 10⁶ W/cm² to 10¹² W/cm², and particularly preferably 10⁸ W/cm² to 10¹¹ W/cm².

The treatment container 3 is a container (for example, a container made of stainless steel) for accommodating at least the target 4 and the substrate 6 in the container, and includes a window 7 (for example a window made of silica glass) for introducing the laser light L₁ to the surface of the target 4 placed in the container 3. In addition, a vacuum pump (not illustrated) is connected to the treatment container 3, so that inner pressure of the container 3 can be maintained at a certain pressure in a reduced pressure state. When the container 3 whose inside is in the reduced pressure state as described above is used, the vacuum-ultraviolet light L₂ is irradiated to the surface of the substrate 6 without being absorbed by a vacuum-ultraviolet light absorbing substance such as oxygen in the air, and the surface of the substrate 6 is more efficiently activated. A pressure when the inside of the container 3 is maintained in the reduced pressure state is preferably 1 Torr or lower, and more preferably 1×10⁻³ Torr or lower. In addition, a partial pressure of oxygen and/or a partial pressure of nitrogen are preferably 1 Torr or lower.

The target 4 may be a material generating flying particles containing aluminum, silicon, titanium, an aluminum compound, a silicon compound and a titanium compound by irradiation of the laser light L₁. Moreover, the target 4 may be a composite material made of aluminum, silicon, titanium, an aluminum compound, a silicon compound and a titanium compound. Shape or the like of the target 4 is not particularly limited, and a bulk material made of the target material formed in a shape of plate, rod or the like and a tape-shaped target formed by applying or vapor-depositing the target material onto a tape can be used. As such aluminum, silicon, titanium, an aluminum compound, a silicon compound and a titanium compound, the same substances described for the above-mentioned laminated body for resin glass according to the present invention can be used.

The substrate 6 is a polymer substrate for resin glass onto the surface of which fine particles should adhere, and is specifically determined as appropriate by an application and the like of an obtained laminated body for resin glass. As these polymer substrates for resin glass, the same polymers described for the above-mentioned laminated body for resin glass of the present invention can be used.

A positional relation of the above-mentioned substrate 6 and the target 4 is not particularly limited. The substrate 6 is placed as appropriate with respect to the target 4 so that the vacuum-ultraviolet light L₂ generated from the surface of the target 4 can be surely irradiated to the surface of the substrate 6 and that the flying particles a can efficiently adhere onto the surface of the substrate 6. In FIG. 1, the substrate 6 is placed at such a position that an angle θ to a normal line of the target 4 is 45 degrees. In addition, a target driving equipment (for example, a target turntable; not illustrated) is connected to the target 4, so that fresh part of the surface (a surface to which laser light has not irradiated yet) of the target can be sequentially placed at an irradiation position of the laser light L₁. Moreover, a substrate driving equipment (for example, a substrate turntable; not illustrated) may be connected to the substrate 6, so that the surface of the substrate 6 can be activated more uniformly.

An embodiment of preferable equipment to perform a process of forming the inorganic layer according to the present invention has been described above. However, preferable equipment to perform these processes is not limited to the equipment described in the above-mentioned embodiment. For example, in the above-mentioned embodiment, the treatment container 3 is connected to a vacuum pump (not illustrated). However, the treatment container 3 may also be connected to a gas cylinder (not illustrated) for introducing at least one shielding gas selected from the group consisting of hydrogen gas, helium gas, neon gas and argon gas. In this case, the inside of the container 3 can be maintained under a given shielding gas atmosphere. When the container 3 whose inside is under shielding gas atmosphere as described above is used, the vacuum-ultraviolet light L₂ can be irradiated to the surface of the substrate 6 without being absorbed by a vacuum-ultraviolet light absorbing substance and the surface of the substrate 6 is more efficiently activated even when inner pressure of the container 3 is not in a reduced pressure state. In addition, it is preferable that both a vacuum pump (not illustrated) and a gas cylinder (not illustrated) are connected to the container 3 and thus inside of the container 3 is made to be under shielding gas atmosphere as well as maintained under a given pressure condition. For such conditions, for example, a pressure less than or equal to atmospheric pressure under helium gas atmosphere is preferable, and a pressure not more that 500 Torr is more preferable. In addition, a partial pressure of oxygen and/or a partial pressure of nitrogen are preferably a pressure of 1 Torr or lower.

In the above-mentioned embodiment, the laser source 2 is placed outside the treatment container 3. However, the laser source 2 may be placed inside of the treatment container 3 and, in that case, the window 7 for introducing the laser light L₁ into the container 3 will not be needed.

Moreover, in the above-mentioned embodiment, the substrate 6 is placed at such a position that an angle θ to a normal line of the target 4 is 45 degrees. However, such a positional relation is not particularly limited, and the substrate 6 may be placed at such a position that an angle θ to a normal line of the target 4 is in the range of about 10 to 60 degrees. In addition, for example, a substrate which can be transparent to the laser light L₁ is used as the substrate 6 made of a carbon containing material and the laser light L₁ passed through the substrate 6 may be irradiated to the target 4 by placing the substrate 6 at opposed position to the target 4 and between the laser source 2 and the target 4.

In addition, a material which can be transparent to the laser light L₁ may be used as the target 4, and the target 4 may be placed between the laser source 2 and the substrate 6. Then, The vacuum-ultraviolet light L₂ and flying particles a are generated from the surface of the target 4 (a target material side) by the laser light L₁ transmitted from the back surface (a transparent film side) to the front surface (a target material side) of the target 4 and vacuum-ultraviolet light L₂ and flying particles a may be supplied to the surface of the substrate 6. When such a configuration is used, formation of an inorganic layer on a relatively large substrate tends to be easier. A target used for such configuration is preferably a tape-shaped target formed by laminating the above-mentioned materials for a target by vapor deposition, pasting or the like on a film which is transparent to the laser light (for example, PET film).

Then, a preferred embodiment for a process of forming an inorganic layer according to the present invention will be described with referring FIG. 1.

Such a process of forming an inorganic layer, first, a pulses laser light L₁ having a pulse width of 100 picoseconds to 100 nanoseconds is irradiated from the laser source 2 to the above mentioned target 4. Then, a high temperature plasma P is formed on the surface of the target 4, and the plasma P generates vacuum-ultraviolet light L₂ having a wavelength of 50 nm to 100 nm. At the same time, molecules containing metal atoms and carbon atoms which depend on the material composing the target fly in all direction in high energy from the surface of the target 4 irradiated by the laser light L₁. In addition, neutral atoms, and ions which are formed by decomposition of molecules composing the target, and clusters formed by bonding of some of the molecules, the neutral atoms and the ions fly in all direction in high energy from the inside of the plasma P or the surface of the target 4 heated by the plasma P. Note that, if the pulse width of pulsed laser light L₁ is lower than 100 picoseconds, light having a wavelength shorter than 50 nm is generated because energy of the laser is intensively irradiated to the target in a short period. On the other hand, if the pulse width of pulsed laser light L₁ is higher than 100 nanoseconds, a wavelength of the generated light exceeds 100 nm because energy of the laser is not intensively irradiated in terms of time. In addition, if the wavelength of the generated light L₂ is lower than 50 nm or higher than 100 nm, in both cases, absorption ratio of the light L₂ to a carbon atom containing material become lower and activation of the surface of the substrate becomes insufficient, so that adhesion strength between the hard coat layer and the substrate becomes insufficient. Moreover, an irradiation intensity of the pulsed laser light L₁ irradiated to target 4 is preferably 10⁶ W/cm² to 10¹² W/cm². If the irradiation intensity of the pulsed laser light L₁ is lower than 10⁶ W/cm², generation of vacuum-ultraviolet light L₂ having a wavelength of 50 nm to 100 nm tends to be insufficient. On the other hand, if the irradiation intensity of the pulsed laser light L₁ is higher than 10¹² W/cm², an amount of vacuum-ultraviolet light L₂ having a wavelength of 50 nm to 100 nm tends to be decreased because main wavelength region of electromagnetic wave generated when the vacuum-ultraviolet light is irradiated to the target becomes a wavelength region of 50 nm or shorter.

Various flying particles (ablator) a generated from the surface of the target 4 by irradiation of the pulsed laser light L₁ as described above are supplied to the surface of the polymer substrate for resin glass 6 together with vacuum-ultraviolet light L₂. Since the vacuum-ultraviolet light L₂ irradiated to the surface of the substrate 6 as described above has high absorption ratio to a material composing the polymer substrate for resin glass, the surface of the polymer substrate for resin glass 6 irradiated by vacuum-ultraviolet light L₂ is sufficiently activated. Since the flying particles a reach there with high energy, the flying particles a strongly adhere onto the substrate 6 and the surface of the substrate is maintained in active condition. Therefore, the surface of the substrate 6 containing carbon atoms can be maintained in active condition without nonuniformity for a long period. By laminating a hard coating layer to such an activated surface of the substrate, alkoxysilane molecules contained in the hard coating layer and the surface of the substrate are strongly bonded. As a result, a highly adhesive hard coating layer is laminated.

In the above-mentioned process of forming the inorganic layer, heating the substrate 6 at high temperature is not required for activating the surface of the substrate 6. Although a substrate temperature is not particularly limited, the temperature may generally be room temperature to about 50° C. In addition, a required time to activate the surface of the substrate 6 (laser light irradiation time) is not also particularly limited, and is determined as appropriate to optimize adhesion between the hard coating layer and the substrate. Generally, the required time is preferably about 1 second to about 10 minutes, and more preferably about 5 second to about 1 minute.

### (Hard Coating Layer Laminating Process)

The process of laminating a hard coating layer according to the present invention is a process of laminating an alkoxysilane-containing hard coating layer on a polymer substrate for resin glass having the inorganic layer interposed therebetween.

For a material for forming such a hard coating layer (a hard coating material), the same material described for the above-mentioned laminated body for resin glass of the present invention can be used.

A method for laminating the hard coating layer on the polymer substrate for resin glass is not particularly limited, and known methods by which the hard coating layer can be laminated onto the polymer substrate for resin glass can be employed as appropriate. For example, employing a method for laminating the hard coating layer by applying the hard coating material is included. Although these applying methods are not particularly limited, various coating methods including a bar coating method, a dip coating method, a flow coating method, a spry coating method and a spin coating method can be employed. Methods for forming (curing) the hard coating layer include methods for curing the hard coating layer by baking and methods for curing the hard coating layer by room temperature drying or heat drying. Although the method for curing the hard coating layer by heat drying is not particularly limited, employing a method of heat curing in the range of 100 to 140° C. for 30 minutes to 2 hours is preferable.

In the present invention, since a hard coating material is applied on the surface of the polymer substrate for resin glass being maintained in an activated condition by the above-mentioned inorganic layer forming process and the reactivity between hard coating material molecules and fine particles forming the inorganic layer is high, the hard coating material molecules and the surface of the substrate are bonded strongly. For this reason, a highly adhesive hard coating is formed without applying a conventional primer coating. In addition, since the surface of the substrate activated in the above-mentioned process of forming the inorganic layer is maintained in activated condition for a long time, the process of laminating the hard coating layer is not necessarily performed immediately after the above-mentioned process of forming the inorganic layer. For example, high adhesion of the hard coating layer is achieved, even when the process of laminating the hard coating layer is performed one or more months after the process of forming the inorganic layer is performed.

### EXAMPLES

The present invention is more specifically described below on the basis of Examples and Comparative Examples.

However, the present invention is not limited to the following examples.

### Example 1 to 3 and Comparative Example 1 to 6

The laminated body for resin glass of each Example was produced by employing a laser ablation method using the equipment illustrated in FIG. 1 for the process of forming the inorganic layer. To be more specific, firstly, laser light was focused onto the target 4 to generate plasma, and ablators a are caused to adhere onto the polymer substrate for resin glass 6 with irradiation with vacuum-ultraviolet light to form the inorganic layer.

As a polymer substrate for resin glass 6, a substrate made of polycarbonate (PC) (Iupilon Sheet (trade name) grade NF2000VU, manufactured by Mitsubishi Engineering-Plastics Corp.) was used. The size of the polymer substrate for resin glass was 40 mm long, 40 mm wide and 2 mm thick.

AS a target 4, the targets each made of a material listed in Table 1 are used.

TABLE 1

| | | Properties, manufacturer, |
|---|---|---|
| | Material | and the like |
| Example 1 | Aluminum (Al) | Composition Al: 99.3%, Si: 0.4%, |
| | | Fe: 0.3% |
| Example 2 | Silicon (Si) | Manufactured by Kojundo Chemical |
| | | Laboratory Co., Ltd. |
| | | Composition Si: 99.999% |
| Example 3 | Titanium dioxide | Manufactured by Kojundo Chemical |
| | (TiO₂) | Laboratory Co., Ltd. |
| | | Composition TiO₂: 99.9% |
| Comparative | Zinc oxide (ZnO) | Manufactured by Kojundo Chemical |
| Example 1 | | Laboratory Co., Ltd. |
| | | Composition ZnO: 99.99% |
| Comparative | Tin (Sn) | Manufactured by Kojundo Chemical |
| Example 2 | | Laboratory Co., Ltd. |
| | | Composition Sn: 99.99% |
| Comparative | Cupper (Cu) | Pure Cupper |
| Example 3 | | |
| Comparative | Iron (Fe) | Pure iron |
| Example 4 | | |
| Comparative | Carbon (C) | Manufactured by Kojundo Chemical |
| Example 5 | | Laboratory Co., Ltd. |
| | | Ash less than 20 ppm |
| Comparative | Carbon (C) | Manufactured by Kojundo Chemical |
| Example 6 | | Laboratory Co., Ltd. |
| | | Ash less than 20 ppm |

As a laser source 2, the pulsed laser (Nd-YAG) equipment, manufactured by Spectra-Physics Inc., was used. The wavelength of laser light was set to 532 nm (pulse width 7 ns, energy 1 J).

The target 4 and the polymer substrate for resin glass 6 was placed so that the angel θ1 between the laser light L₁ and the surface of the target 4 shown in FIG. 2 was 25 degrees; the angel θ2 between the normal line of polymer substrate for resin glass 6 and the laser light L₁ was 60 degrees; and the distance X between the target 4 and the polymer substrate for resin glass 6 was 80 mm. In addition, the target 4 and the polymer substrate for resin glass 6 are rotated at 6 rpm and 48 rpm respectively by motors in order to perform uniform treatment. Moreover, the degree of vacuum in the treatment container was maintained at 10⁻³ Torr or lower during experiments.

The shape of the focused laser light was adjusted to have an average diameter of 3.2 mm, and an irradiation intensity condition of the laser light was 1.7 GW/cm². Note that, irradiation intensity can be determined by light focusing size of the laser light (a spot area of the laser light on the target), and the relation between irradiation intensity and light focusing size was represented by the following formula (1):

(Irradiation intensity)=(Laser light energy)/{(Pulse width)×(Light focusing size)} (1)

The treatment time by this laser light was set to 30 seconds.

Then, as the process of laminating the hard coating layer, a hard coating layer was laminated to the polymer substrate for resin glass having the inorganic layer interposed therebetween in such a way that an alkoxysilane-containing hard coating material (KP-851, manufactured by Shin-Etsu Chemical Co., Ltd.) is applied by dipping, and then dried. A laminated body for resin glass was obtained as described above. As for an applying condition and a drying condition of this hard coating material, dipping coating was performed once (for about 1 min) to the substrate on which the inorganic layer was formed, then the coated substrate was left for 20 min for setting. Thereafter baking was performed at a temperature condition of 130° C. for 60 min. Note that, the thickness of the hard coating layer in the obtained the laminated body for resin glass was 4 μm.

### Example 4

A laminated body for resin glass was produced in a similar way to Example 2 except that a substrate of polymethyl methacrylate produced by the method to be described below was used as the polymer substrate for resin glass and baking was performed at a temperature condition of 100° C. for 120 min.

[Substrate made of Polymethyl Methacrylate]

Polymethyl methacrylate (PMMA: Delpet (trade name) grade 80N, manufactured by Asahi Kasei Corporation) was used as a material. The Delpet was molded by the injection molding machine (NEX1000-9E TWF-200HHDN (trade name) manufactured by Nissei Plastic Industrial Co., Ltd.) with a condition of a clamping pressure of 80 tons to obtain a molded substrate of 2 mm thickness. The obtained molded substrate was cut to form a substrate having the size of 40 mm long, 40 mm wide and 2 mm thick. Thus, the substrate made of polymethyl methacrylate was obtained.

### Example 5

A laminated body for resin glass was produced in a similar way to Example 3 except that a substrate made of polymethyl methacrylate similar to that used in Example 4 was used as the polymer substrate for resin glass and baking was performed at a temperature condition of 100° C. for 120 min.

### Comparative Example 7

A laminated body for resin glass was produced in a similar way to Comparative Example 5 except that a substrate made of polymethyl methacrylate similar to that used in Example 4 was used as the polymer substrate for resin glass and baking was performed at a temperature condition of 100° C. for 120 min.

### Comparative Example 8

A laminated body for resin glass was produced in a similar way to Comparative Example 6 except that a substrate made of polymethyl methacrylate similar to that used in Example 4 was used as the polymer substrate for resin glass and baking was performed at a temperature condition of 100° C. for 120 min.

### <Evaluation of Properties of the Laminated Bodies for Resin Glass Obtained in Examples 1 to 5 and Comparative Examples 1 to 8>

### <Initial Adhesion>

Tape peeling test was conducted on the laminated bodies for resin glass obtained in Examples 1 to 5 and Comparative Examples 1 to 8 to evaluate initial adhesion. To be more specific, in the tape peeling test, after a hard coating layer of each laminated body for resin glass was crosscut with a cutter knife, Sellotape (registered trademark) CT-24 manufactured by Nichiban Co., Ltd. was stuck to the crosscut part and the tape was peeled. The initial adhesion was evaluated by existence or nonexistence of peeled hard coating. Note that, the criteria for the tape peeling test are as follows:

### [Evaluation Criteria of Initial Adhesion]

A: A hard coat was not peeled off (acceptable).
C: A hard coat was peeled off (not acceptable).
The obtained results were listed in Table 2. Note that, the following evaluations were not conducted on Comparative Example 5 to 8, which had poor initial adhesion.

### <Heat Resistance>

Heat resistance of the laminated bodies for resin glass obtained in Examples 1 to 5 and Comparative Examples 1 to 4 was evaluated. To be more specific, after heat resistance test was conducted in which each laminated body for resin glass was maintained under a temperature condition of 110° C. for 720 hours, tape peeling test employing a similar method to the method employed in the initial adhesion evaluation was conducted to evaluate heat resistance. Note that, the evaluation criteria are the same as the evaluation criteria for the initial adhesion evaluation. The obtained results are listed in Table 2.

### <Moisture Resistance>

Moisture resistance of the laminated bodies for resin glass obtained in Examples 1 to 5 and Comparative Examples 1 to 4 was evaluated. To be more specific, after moisture resistance test was conducted in which each laminated body for resin glass was maintained under a temperature condition of 50° C. and a relative humidity condition of 95% for 720 hours, tape peeling test employing a similar method to the method employed in the initial adhesion evaluation was conducted to evaluate moisture resistance. The obtained results are listed in Table 2.

### <Water Resistance>

Water resistance of the laminated bodies for resin glass obtained in Examples 1 to 5 and Comparative Examples 1 to 4 was evaluated. To be more specific, after water resistance test was conducted in which each laminated body for resin glass was immersed in water at a temperature of 40° C. for 720 hours, tape peeling test employing a similar method to the method employed in the initial adhesion evaluation was conducted to evaluate water resistance. The obtained results are listed in Table 2.

### <Thermal Shock Resistance>

Thermal shock resistance of the laminated bodies for resin glass obtained in Examples 1 to 5 and Comparative Examples 1 to 4 was evaluated. To be more specific, after thermal shock resistance test was conducted in which each laminated body for resin glass was alternately exposed to a temperature of −30° C. for 90 min and 110° C. for 90 min and 100 cycles of this exposure was repeated, tape peeling test employing a similar method to the method employed in the initial adhesion evaluation was conducted to evaluate thermal shock resistance. The obtained results are listed in Table 2.

### <Weatherability>

Weatherability of the laminated bodies for resin glass obtained in Examples 1 to 5 and Comparative Examples 1 to 4 was evaluated. To be more specific, accelerated weatherability test described below was conducted to evaluate weatherability. For this accelerated weatherability test, the accelerated weatherability test equipment (KU-R5C1-A (trade name), manufactured by Daipla Wintes Co., Ltd.) using a metal halide lamp as a light source was used as a test equipment. After three conditions, that is, light irradiation condition, darkness condition and dew formation condition, were sequentially applied, a number of cycles was counted until the hard coating peeled off by itself. The above-mentioned irradiation condition was that a light was irradiated for 4 hours under a condition of a lightning intensity of 90 mW/cm², a black panel temperature of 63° C. and a relative humidity of 70%. The above-mentioned darkness condition was that no light irradiation was maintained for 4 hours under a condition of a black panel temperature of 70° C. and a relative humidity of 90%. The above-mentioned dew formation condition was that a temperature of black panel was naturally cooled from 70° C. to 30° C. under a condition of a relative humidity of 98% without light irradiation, and this state was maintained for 4 hours. The obtained results are listed in Table 2.

### <Abrasion-Resistance>

In order to evaluate abrasion-resistance, Tabor abrasion test was conducted on the laminated bodies for resin glass obtained in Examples 1 to 5 and Comparative Examples 1 to 4. To be more specific, Tabor abrasion test was conducted on each laminated bodies for resin glass using a Tabor abrasion tester equipped with CS-10F abrasion wheels with a load of 500 g for each wheel for 500 cycles. The difference (ΔH) between a haze before Tabor abrasion test and a haze after Tabor abrasion test was measured to evaluate abrasion-resistance. The obtained results are listed in Table 2.

TABLE 2

| | Material | | Irradiation | | | Thermal | | | | Abrasion |
|---|---|---|---|---|---|---|---|---|---|---|
| | of | | intensity | Initial | Heat | shock | Moisture | Water | | resistance |
| | substrate | Target | (GW/cm²) | adhesion | resistance | resistance | resistance | resistance | Weatherability | ΔH (%) |
| Example 1 | PC | Al | 1.5 | A | A | A | A | A | 18 | 9.1 |
| Example 2 | | Si | 1.5 | A | A | A | A | A | 106 | 7.2 |
| Example 3 | | TiO₂ | 1.5 | A | A | A | A | A | 128 | 10.5 |
| Comparative | | ZnO | 1.5 | A | C | A | C | C | 4 | 11.3 |
| Example 1 | | | | | | | | | | |
| Comparative | | Sn | 1.5 | A | C | C | C | C | 4 | 13.1 |
| Example 2 | | | | | | | | | | |
| Comparative | | Cu | 1.5 | A | A | A | A | C | 8 | 9.4 |
| Example 3 | | | | | | | | | | |
| Comparative | | Fe | 1.5 | A | A | A | C | C | 8 | 8.7 |
| Example 4 | | | | | | | | | | |
| Comparative | | C | 1.5 | C | — | — | — | — | — | — |
| Example 5 | | | | | | | | | | |
| Comparative | | C | 4.6 | C | — | — | — | — | — | — |
| Example 6 | | | | | | | | | | |
| Example 4 | PMMA | Si | 1.5 | A | A | A | A | A | 100 | 5.7 |
| Example 5 | | TiO₂ | 1.5 | A | A | A | A | A | 112 | 7.5 |
| Comparative | | C | 1.5 | C | — | — | — | — | — | — |
| Example 7 | | | | | | | | | | |
| Comparative | | C | 4.6 | C | — | — | — | — | — | — |
| Example 8 | | | | | | | | | | |

### Examples 6 to 9

By employing a spattering method for the process of forming the inorganic layer and by employing a process of laminating the hard coating layer similar to the process of laminating the hard coating layer employed in Example 1, laminated bodies for resin glass were produced.

To be more specific, the inorganic layer was formed onto the polymer substrate for resin glass by spattering treatment using spattering equipment (manufactured by Ulvac, Inc.). Thereafter, a laminated body for resin glass was obtained by laminating a hard coating layer. Then, the process of laminating the hard coating layer was preformed to produce the laminated body for resin glass. In such a spattering treatment, the base material made of the same material used in Example 2 was used in each Example 6 and 7 as the target, and the base material made of the same material used in Example 3 was used in each Example 8 and 9 as the target. In addition, the substrate made of the same polycarbonate (PC) used in Example 1 was used as the polymer substrate for resin glass.

In the spattering treatment, first, the substrate cut into 40 mm long and 40 mm wide was fixed to a sample holder in the spattering equipment, and the inside of the equipment was vacuumed by a vacuum pump and an oil diffusion pump down to 2×10⁻⁶ Torr. After the pressure of the inside of the equipment reaches 2×10⁻⁶ Torr, Ar gas (in the case where the target is Si (in the case of Example 6 and 7)), or mixed gas of Ar and O₂ (in the case where the target is TiO₂ (in the case of Example 8 and 9)) was introduced to the inside of equipment up to a pressure condition of 3×10⁻⁶ Torr. Then, electric power of 50 W (in the case of Example 6 and 7) or 150 W (in the case of Example 8 and 9) was supplied to the power source of the target to generate plasma. After plasma was generated as described above, the plasma was irradiated to the substrate for a certain time period (Example 6: 90 sec, Example 7: 50 sec, example 8: 330 sec and Example 9: 155 sec). After that, power source of the target was turned off, and after the target was cooled, the pressure was increased to the atmospheric pressure using nitrogen. Then the substrate was taken out from the equipment. Each thickness of the obtained inorganic layer is listed in Table 3.

### Example 10

A laminated body for resin glass was produced in a similar way to Example 6 except that a substrate made of polymethyl methacrylate similar to that used in Example 4 was used as the polymer substrate for resin glass and baking was performed at a temperature condition of 100° C. for 120 min. The thickness of the obtained inorganic layer is listed in Table 3.

### Example 11

A laminated body for resin glass was produced in a similar way to Example 7 except that a substrate made of polymethyl methacrylate similar to that used in Example 4 was used as the polymer substrate for resin glass and baking was performed at a temperature condition of 100° C. for 120 min. The thickness of the obtained inorganic layer is listed in Table 3.

### Example 12

A laminated body for resin glass was produced in a similar way to Example 8 except that a substrate made of polymethyl methacrylate similar to that used in Example 4 was used as the polymer substrate for resin glass and baking was performed at a temperature condition of 100° C. for 120 min. The thickness of the obtained inorganic layer is listed in Table 3.

### Example 13

A laminated body for resin glass was produced in a similar way to Example 9 except that a substrate made of polymethyl methacrylate similar to that used in Example 4 was used as the polymer substrate for resin glass and baking was performed at a temperature condition of 100° C. for 120 min. The thickness of the obtained inorganic layer is listed in Table 3.

### <Evaluation of Properties of the Laminated Bodies for Resin Glass Obtained in Examples 6 to 13>

Initial adhesion, heat resistance, weatherability and abrasion resistance of the laminated bodies for resin glass obtained in Examples 6 to 13 was evaluated. For evaluation methods of such initial adhesion, heat resistance, weatherability and abrasion resistance, employed methods were the evaluation methods of initial adhesion, heat resistance, weatherability and abrasion resistance employed in the above-mentioned Examples 1 to 5 and Comparative Examples 1 to 8. The obtained results are listed in Table 3.

TABLE 3

| | Material | Material | | Film | | | | Abrasion |
|---|---|---|---|---|---|---|---|---|
| | of | of | Treatment | thickness | Initial | Water | | resistance |
| | substrate | target | time (s) | (nm) | adhesion | resistance | Weatherability | ΔH (%) |
| Example 6 | PC | Si | 90 | 8.8 | A | A | 50 | 7.4 |
| Example 7 | | | 50 | 4.4 | A | A | 22 | 7.1 |
| Example 8 | | TiO₂ | 330 | 8.8 | A | A | 64 | 9.8 |
| Example 9 | | | 155 | 4.4 | A | A | 28 | 8.7 |
| Example 10 | PMMA | Si | 90 | 8.8 | A | A | 40 | 6.3 |
| Example 11 | | | 50 | 4.4 | A | A | 36 | 5.9 |
| Example 12 | | TiO₂ | 330 | 8.8 | A | A | 50 | 7.1 |
| Example 13 | | | 155 | 4.4 | A | A | 30 | 6.8 |

As is apparent from the results listed in Tables 2 and 3, it is observed that all the properties of each of the laminated bodies for resin glass according to the present invention whose inorganic layers are each made of aluminum, silicon or titania (Example 1 to 13) were excellent. In contrast, water resistance and weatherability of all resin glass of the laminated bodies for resin glass whose inorganic layers are each made of other than aluminum, silicon and titania (Comparative Example 1 to 7), were inferior to those of each of the laminated bodies for resin glass of the present invention (Examples 1 to 5).

### INDUSTRIAL APPLICABILITY

As described above, according to the present invention, it is possible to provide a laminated body for resin glass, and a method for manufacturing the laminated body for resin glass capable of efficiently and reliably manufacturing the laminated body for resin glass. The laminated body for resin glass has sufficiently high adhesion between a polymer substrate for resin glass and a hard coating layer without a conventional primer coating being performed, and can exhibit excellent abrasion-resistance as well as high weatherability by which the polymer substrate for resin glass is sufficiently prevented from degradation caused by ultraviolet irradiation.

Accordingly, since the laminated body for resin glass of the present invention has excellent adhesion and weatherability, the laminated body for resin glass is particularly useful as a material for a resin glass used for a window component for an automobile and the like.

1. A laminated body for resin glass comprising:
a polymer substrate for resin glass;
an inorganic layer formed by causing fine particles of at least one substance selected from the group consisting of aluminum, silicon, titanium, an aluminum compound, a silicon compound and a titanium compound to adhere onto the polymer substrate for resin glass; and
an alkoxysilane-containing hard coating layer laminated to the polymer substrate for resin glass having the inorganic layer interposed therebetween,
said inorganic layer being formed: by irradiating laser light to a surface of a base material to generate vacuum-ultraviolet light having a wavelength of 50 nm to 100 nm and flying particles; and by causing the flying particles to adhere onto the polymer substrate for resin glass with irradiation of the vacuum-ultraviolet light, said base material being made of a material comprising at least one substance selected from the group consisting of aluminum, silicon, titanium, an aluminum compound, a silicon compound and a titanium compound.

2. (canceled)

3. The laminated body for resin glass according to claim 1, wherein the polymer substrate for resin glass comprises at least one resin selected from the group consisting of a polycarbonate resin, a polymethyl methacrylate resin, a methyl methacrylate resin, a transparent acrylonitrile butadiene styrene resin, a transparent polystyrene resin, a transparent epoxy resin, a polyarylate, a polysulfone, a polyethersulfone, a transparent nylon resin, a transparent polybutylene terephthalate, a transparent fluororesin, poly-4-methylpentene-1, a transparent phenoxy resin, a polyimide resin and a transparent phenol resin.

4. The laminated body for resin glass according to claim 1, wherein the polymer substrate for resin glass comprises a polycarbonate resin.

5. A method for manufacturing a laminated body for resin glass, the method comprising the steps of:
forming an inorganic layer by causing fine particles of at least one substance selected from the group consisting of aluminum, silicon, titanium, an aluminum compound, a silicon compound and a titanium compound to adhere onto a polymer substrate for resin glass; and
laminating an alkoxysilane-containing hard coating layer to the polymer substrate for resin glass having the inorganic layer interposed therebetween,
said step of forming the inorganic layer being a step of forming an inorganic layer: by irradiating laser light to a surface of a base material to generate vacuum-ultraviolet light having a wavelength of 50 nm to 100 nm and flying particles; and by causing the flying particles to adhere onto the polymer substrate for resin glass with irradiation of the vacuum-ultraviolet light, said base material being made of a material comprising at least one substance selected from the group consisting of aluminum, silicon, titanium, an aluminum compound, a silicon compound and a titanium compound.

6. (canceled)

7. The method for manufacturing a laminated body for resin glass according to claim 6, wherein the laser light is a pulsed laser light having a pulse width of 100 picoseconds to 100 nanoseconds and an irradiation intensity of 10⁶ W/cm² to 10¹² W/cm².

8. The method for manufacturing a laminated body for resin glass according to claim 6, wherein the flying particles are caused to adhere onto the surface of the polymer substrate for resin glass under a reduced pressure condition and/or a shielding gas atmosphere comprising at least one gas selected from the group consisting of hydrogen gas, helium gas, neon gas and argon gas.

9. The method for manufacturing a laminated body for resin glass according to claim 5, wherein the polymer substrate for resin glass comprises at least a resin selected from the group consisting of a polycarbonate resin, a polymethyl methacrylate resin, a methyl methacrylate resin, a transparent acrylonitrile butadiene
